(19) United States
(12) Patent Application Publication
(10) Pub. No.: US 2007/0030499 A1
(43) Pub. Date: Feb. 8, 2007

(54) COLOR PROCESSING METHOD AND APPARATUS

(75) Inventor: Ayumi Hori, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/459,499

(22) Filed: Jul. 24, 2006

(30) Foreign Application Priority Data
Aug. 2, 2005 (JP) 2005-224594

(51) Int. Cl. G03F 3/08

(52) U.S. Cl. 358/1.9; 358/518; 358/504

(57) ABSTRACT

In order to implement satisfactory color reproduction which effectively uses the gamut of an output device without causing any tone burning-out in only a specific gamut, a gamut that can attain colorimetrically approximate mapping must be set in consideration of the characteristics of colors and gamuts. Hence, upon converting a first gamut onto a second gamut, a third gamut having a shape according to the characteristics of the color or gamut is set inside the second gamut. The first gamut included in the third gamut is mapped onto the second gamut which is colorimetrical matching or approximate to the first gamut. The first gamut outside the third gamut is mapped onto the second gamut outside the third gamut.

### BACKGROUND OF THE INVENTION

1. Field of the Invention

The present invention relates to color processing for converting a first gamut into a second gamut.

2. Description of the Related Art

In recent years, digital imaging apparatus such as digital cameras, image scanners, and the like have prevailed, and digital images can be readily acquired. On the other hand, the full-color hard copy technique is evolving at a rapid pace. Especially, printing using an ink-jet system can assure print image quality equivalent comparable to silver halide photos, and is popularly used. Networks such as the Internet and the like have prevailed, and many users are in an environment in which various devices can be connected to the network. In such environment with diversified input and output devices, there are many opportunities to input and output color image data between devices having different gamuts. For example, a hard copy of a color image on a monitor with a broad gamut is formed by a printer having a different gamut.

As a technique for attaining identical color reproduction between devices having different gamuts, a color management system (to be referred to as “CMS” hereinafter) is prevalent. FIG. 1 is a view showing an overview of the arrangement of this CMS, and shows the CMS which uses a device-independent color space.

FIG. 1 shows an example in which input devices (a camera, scanner, and the like) and output devices (a printer, monitor, and the like) are connected. In this case, conversion from a color signal of the input system into that of an output system is implemented via profiles of the devices and a profile connection space (PCS). Note that the PCS is a device-independent color space, and for example, CIEXYZ, CIELab, and the like are available. Each profile is provided as a lookup table (LUT) as a conversion table which describes conversion formulas that connect respective device colors and the PCS or the relationship between device colors and the PCS.

FIG. 2 is a block diagram showing the basic arrangement of the CMS.

Referring to FIG. 2, an image processing apparatus 201 is a computer apparatus which executes color processing and the like associated with the CMS. An image input device 202 is a device such as a camera, scanner, or the like which inputs an image to the image processing apparatus 201. An image display device 203 is a device such as a monitor which displays an image. An image output device 204 is a device such as a printer which prints out an image supplied from the image processing apparatus 201.

In the image processing apparatus 201, an image input unit 205 inputs an image from the image input device 202. An image display unit 206 generates a signal required to display an image on the image display device 203. A color matching processor 207 performs color matching between the colors of an image which is input from the image input device 202 and is displayed on the image display device 203 with those of an image which is printed out by the image output device 204. An image processor 208 performs tone conversion processing, color conversion processing, and the like of an image to be output to the image output device 204. An image output unit 209 generates a signal required to output an image to the image output device 204.

Furthermore, the image processing apparatus 201 comprises a camera profile (or scanner profile) 210 for the image input device 202. Also, the image processing apparatus 201 comprises a monitor profile 211 for the image display device 203 and a printer profile 212 for the image output device 204. Note that the profiles 210 to 212 are stored as data files in a storage device such as a hard disk or the like.

The system shown in FIG. 2 has an advantage of easily coping with different devices by changing the profiles 210 to 212 to be used in correspondence with input and output devices even when input and output devices connected are changed.

In order to allow the output device to reproduce colors that can be acquired by the input device, or in order to allow the input device to acquire colors which can be reproduced by the output device, the CMS uses a mapping technique that can absorb the influences of different gamuts between the input and output devices.

For example, Japanese Patent Laid-Open No. 6-225130 describes a general mapping method between input and output devices with different gamuts. That is, this reference describes a method of converting an input color space into a device-independent color space (uniform color space), and mapping colors, which cannot be reproduced by the output device of those of this color space in a minimum color difference direction, and a method of performing nonlinear mapping according to saturation in a constant lightness direction. A method described in Japanese Patent Laid-Open No. 4-40072 converts an input color space into a uniform color space or HVC color space as a device-independent color space, and checks if a color of this color space falls outside a gamut at the output destination. When the color falls outside the gamut, that color is mapped on a color which has the same lightness and hue values and a maximum saturation value.

However, with the method of faithfully reproducing the colors of the input color space, which can be reproduced by the output device, and mapping colors which cannot be reproduced by the output device on the boundary of the gamut, the colors which cannot be reproduced by the output device cause tone burning-out, thus disabling satisfactory color reproduction.

Upon mapping the input color space on the gamut of the output device, a method of linearly mapping saturation is available. Let DS be the boundary of saturation of the input color space, and DI be that of saturation of the printer gamut. Then, the compression ratio of saturation is DI/DS. Such method outputs a different color even when an identical color is input, if the gamut of the output device has changed. That is, such method poses a problem that colors to be reproduced change if the output device and print media change.

In order to solve these two problems, Japanese Patent Laid-Open No. 2003-153020 discloses the following method. That is, when the first gamut is converted to the second gamut, a common region of the two gamuts is extracted, and a region outside the common region of the first gamut is mapped on a region outside the common region of the second gamut. The common region (colorimetrical matching gamut) which is not mapped may partially or entirely have a similar shape to the shape of the first gamut. Using such method, even when the gamut of the output device changes, colors within the common region are not influenced by such change, and colorimetrically approximated color reproduction can be obtained. Of course, since mapping is done for colors outside the common region, the tone balance can be maintained in the second gamut for those outside the common region.

However, the technique described in Japanese Patent Laid-Open No. 2003-153020 suggests that the gamut (colorimetrical matching gamut) being not mapped is the common region, and the shape of the gamut partially or entirely has a similar shape to the shape of the first gamut. However, the gamut (colorimetrical matching gamut) being not mapping cannot always be adaptively set according to the shapes of the first and second gamuts. Also, the common region (colorimetrical matching gamut) being not mapped is not set according to features of colors or gamuts. For this reason, color burning-out may occur in a given gamut, or changes in lightness and saturation due to mapping become large, thus disturbing satisfactory color reproduction.

Problems in mapping which sets a non-mapping region (to be referred to as a “colorimetrical matching region” hereinafter) which colorimetrically matches the colors of the input color space and the output device will be described below.

Tone Burning-out Depending on Gamut

FIG. 3 is a view for explaining the relationship between a general sRGB color space 301 of a monitor or digital camera, and a gamut 302 of an ink-jet printer as a typical output device.

The sRGB color space 301 and printer gamut 302 have different shapes and sizes. This is because color expression of the monitor or digital camera is done based on the principle of the additive process of red, green, and blue, and that of the ink-jet printer is done based on the principle of the subtractive process of cyan, magenta, and yellow inks. In other words, the gamuts have different shapes and sizes due to differences of color separations and color development principles unique to devices. As shown in FIG. 3, as a cyan region has a broad overlapping range between the two regions, a color region (to be referred to as “region to be mapped”) of the sRGB color space 301 to be mapped becomes narrow. On the other hand, overlapping range between the two regions in a green region is small, and its region to be mapped is broad. For this reason, the region to be mapped, which is broader than that of the cyan region, is mapped into the gamut 302 in the green region, thus the green region readily causes tone burning-out.

Color Differences Depending on Gamut

If a copying machine is assumed as the output device, its principal use is a copy function. In general, originals to be copied by the copying machine are normally printed matters, and copies are often re-printed (second generation copies).

FIG. 4 is a view for explaining the positional relationship among the boundary of the sRGB color space, that of the printer gamut, and that of the colorimetrical matching region, and shows a gamut section at a given lightness level. Note that a point O is a convergence point of mapping.

For example, if an original includes colors 401 and 404 near the boundary of the sRGB color space, they are respectively mapped to the positions of colors 402 and 405 of the printer gamut to form a copy. Upon forming a second generation copy using this printed matter (copy) as an original, the colors 402 and 405 are respectively mapped to the positions of colors 403 and 406, thus forming a copy. Paying attention to changes in color, the two colors are printed to have nearly equal saturation values in the first copy. However, as a result of formation of the second copy (second generation copy), a saturation drop from the color 402 to the color 403 is larger than that from the color 405 to the color 406. In other words, a color difference between the original and second generation copy in a given gamut is small, but that between the original and second generation copy is large in another gamut.

Colors Having Less Chances to be Input

If an ink-jet printer is assumed as the output device, its use application includes printing of images sensed by a digital camera. The input color space of a general digital camera is an sRGB color space, but the gamut which is input in practice is normally narrower than the sRGB color space. For example, high-saturation green (a color that Lab values are about (87, −86, 83)) on the sRGB color space is a color which does not have any unnecessary absorption/reflection characteristics and has a spectrum of only a green wavelength range. That is, there is nearly no such high-saturation green except for a peculiar object such as a phosphor or the like. Therefore, an input image rarely includes high-saturation green.

That is, the input color space includes colors which have less chances to be input, and an actually input gamut is narrower than the sRGB color space. If a broad region to be mapped of the gamut which includes colors having less chances to be input is set, a region corresponding to the colors having less chances to be input is set in the gamut 302. Therefore, an area of a region corresponding to colors having many chances to be input is reduced. For this reason, the tone balance of the gamut which includes the colors having many chances to be input is impaired, and the gamut of the output device cannot be effectively used.

Accordingly, the colorimetrical matching region must be adaptively set in consideration of the use applications and characteristics of the input and output devices.

Human Perception Characteristics

In general, human perception is hard to identify changes in color with increasing saturation. Therefore, the high-saturation region of green on the sRGB color space is the gamut in which changes in colors are hard to perceive. On the other hand, with colors in a red region (a region that Lab values are about (53, 80 67)) on the sRGB color space, since they have lower saturation than green, changes in color are easier to perceive. For this reason, nearly no problem is posed even when a broad colorimetrical matching region is set in the green region, which causes burning-out of the tone balance of the gamut with high saturation. However, when the colorimetrical matching region of the red region is set to have the same area as that of the green area, color burning-out stands out.

In other words, the colorimetrical matching region must be adaptively set to implement favorable color reproduction.

### SUMMARY OF THE INVENTION

The first aspect of the present invention discloses a color processing method of converting a first gamut onto a second gamut, the method comprising the steps of: setting a third gamut having a shape according to characteristics of a color or a gamut inside the second gamut; mapping the first gamut included in the third gamut onto the second gamut which is colorimetrically matched or approximate to the first gamut; and mapping the first gamut outside the third gamut onto the second gamut outside the third gamut.

The second aspect of the present invention discloses a color processing apparatus for converting a first gamut onto a second gamut, the method comprising the steps of: a setter, arranged to set a third gamut having a shape according to characteristics of a color or a gamut inside the second gamut; and a mapper, arranged to map the first gamut included in the third gamut onto the second gamut which is colorimetrically matched or approximate to the first gamut, and to map the first gamut outside the third gamut onto the second gamut outside the third gamut.

According to the present invention, perceptive mapping can be done by setting colorimetrical matching or approximate gamuts in consideration of the characteristics of a given color and gamut. Therefore, satisfactory color reproduction that effectively uses the gamut of an output device without causing tone burning-out in only a specific gamut can be realized.

Further features of the present invention will become apparent from the following description of exemplary embodiments with reference to the attached drawings.

### BRIEF DESCRIPTION OF THE DRAWINGS

FIG. 1 is a view showing an overview of the arrangement of a CMS;

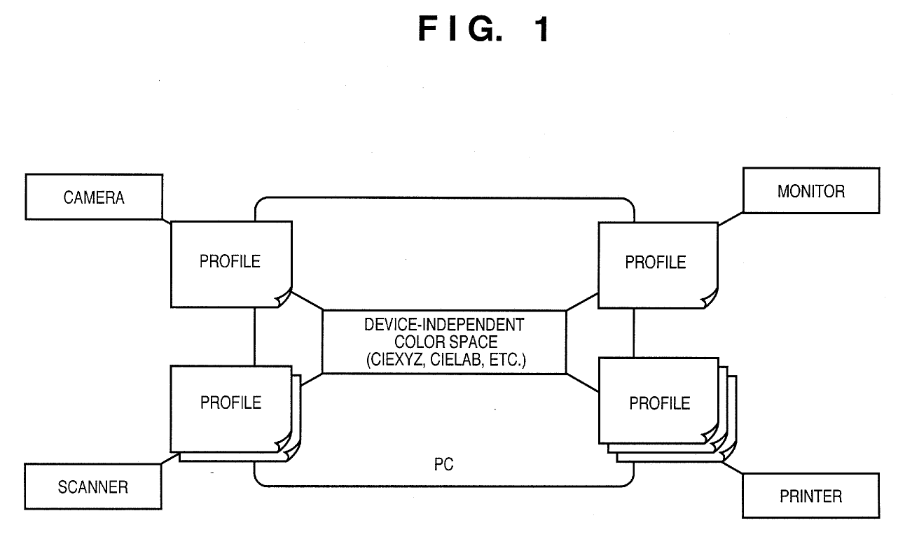

FIG. 2 is a block diagram showing the basic arrangement of the CMS;

FIG. 3 is a view for explaining the relationship between an sRGB color space and printer gamut;

FIG. 4 is a view for explaining the positional relationship among the boundaries of the sRGB color space, printer gamut, and colorimetrical matching region;

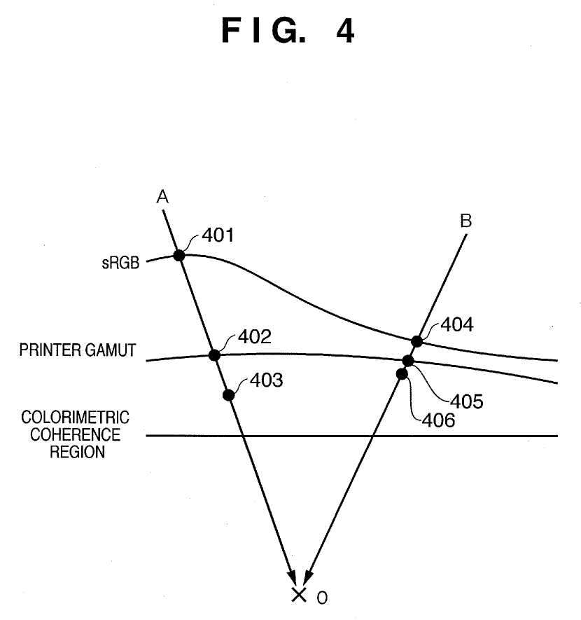

FIG. 5 shows the relationship between the hue and lightness values of basic color points;

FIG. 6A shows an a*b* plane of a printer gamut;

FIG. 6B shows an L*a* plane of the printer gamut;

FIG. 7 is a view showing a state wherein grid points are plotted on the view showing control points;

FIG. 8 is a view for explaining mapping upon setting a colorimetrical matching region;

FIG. 9 is a flowchart for explaining the adaptive setting sequence of the colorimetrical matching region according to colors and mapping;

FIG. 10 shows an example of a UI used to set reduction ratios at respective control points according to the second embodiment of the present invention;

FIG. 11 is a graph expressing, as a function, the reduction ratios of control points with lightness L_{High};

FIG. 12 is a graph showing the reduction ratios of control points whose lightness is other than L_{High};

FIG. 13 shows a UI used to set the reduction ratio of a specialized region;

FIG. 14 is a graph showing an example of control functions of the control point of L_{High}, which are set in advance, according to the third embodiment of the present invention;

FIG. 15 is a graph showing an example of control functions of control points other than L_{High}; and

FIG. 16 shows a UI used to select control functions.

### DESCRIPTION OF THE EMBODIMENTS

Color processing according to preferred embodiments of the present invention will be described in detail hereinafter with reference to the accompanying drawings. In the following description, as an example, the type of an input color space is an sRGB color space as a general input color space of a digital camera, and an output device is an ink-jet printer. Also, the PCS handles a CIELab color system. However, the present invention is not limited to the CIELab color system, and uniform color spaces such as an Luv color space and the like may be used. An example of mapping the sRGB color space expressed by the CIELab color system onto the printer gamut will be described below.

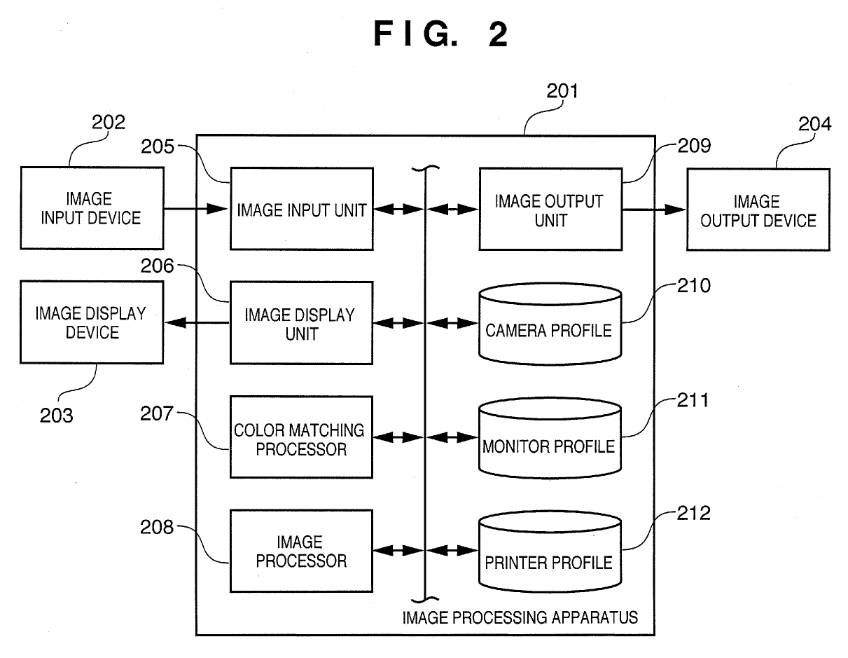

Note that the processing to be described below is executed by the image processing apparatus 201 shown in FIG. 2.

### First Embodiment

A method of adaptively setting a colorimetrical matching region according to colors will be described first. In the first embodiment, the colorimetrical matching region is determined by reducing the gamut of the output device.

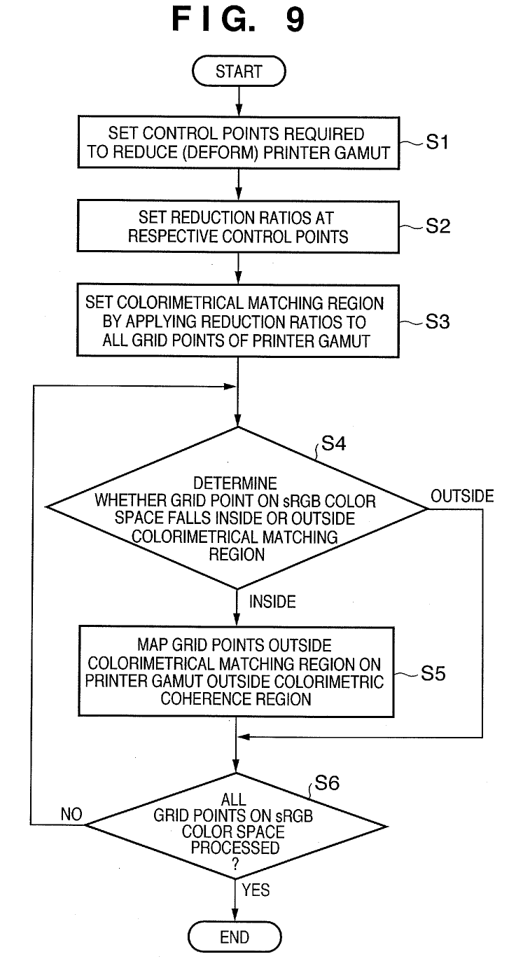

FIG. 9 is a flowchart for explaining the adaptive setting sequence of the colorimetrical matching region according to colors, and mapping. This processing is executed by the image processor 208.

Control points used to reduce (deform) the printer gamut are set with reference to the printer gamut (S1). The sRGB color space and printer gamut are respectively divided in advance by predetermined grid points, and data of the grid points are expressed by the CIELab color system. When the respective gamuts are expressed by discrete grid points, and the remaining region is connected by linear interpolation, they can be analyzed as continuous color spaces. A method of setting control points will be described below. Note that each control point is given by a hue value and lightness value.

Assume that the hue values of control points are those of basic color points of the sRGB color space. The basic colors mean six basic colors, i.e., red, green, and blue as the primary colors of the sRGB color space, and cyan, magenta, and yellow as mixed colors (secondary colors) of the basic colors. By setting the control points as the colors of the input color space, for example, when an input device is a digital camera, it becomes easy to determine the colorimetrical matching region while analyzing an input image. CIELab values at the respective basic color points of the sRGB color space are acquired. The sRGB color space is specified by 0≦R≦255, 0≦G≦255, and 0≦B≦255. Therefore, the basic color points of the sRGB color space meet the following conditions. RGB values which meet these conditions can be converted into Lab values.

Red R=255, G=0, B=0

Yellow R=255, G=255, B=0

Green R=0, G=255, B=0

Cyan R=0, G=255, B=255

Blue R=0, G=0, B=255

Magenta R=255, G=0, B=255

Hue values H of the basic color points obtained in this way are calculated using:
H=tan⁻¹(b*/a*) (1)
These values are used as those of the control points.

Lightness values of the control points are then determined. For the sake of simplicity, assume that the lightness values of the control points are set at points that divide the lightness range between a black point (process black) of the printer gamut and a white point (paper white) into four. The black point is described as L_{Black}, and those in ascending order of lightness are respectively describes as L_{LOW}, L_{Mid}, and L_{High}, and the white point is described as L_{White}. For example, in a photo-grade paper, lightness of the black point of is about 5, and lightness of the white point is about 95, thus L_{Low} is set up in 27.5, L_{Mid} is set up in 50, and L_{High} is set up in 72.5.

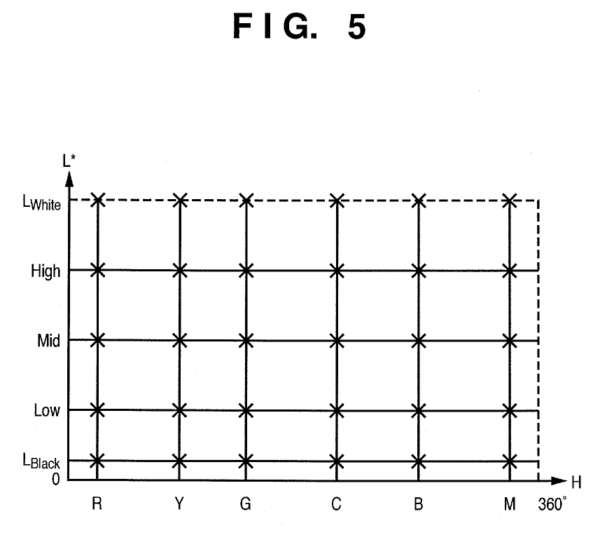

FIG. 5 shows the relationship between the hue and lightness values of the basic color points. The hue values of the basic color points are respectively those of red R (hue is about 40), yellow Y (hue is about 102), green G (hue is about 136), cyan C (hue is about 196), blue B (hue is about 306), and magenta M (hue is about 328).

That is, intersections (30 points) between the hue values H of the basic color points and set lightness values L* are control points. In the following description, a control point of low lightness of red R is described as a point RL_{Low}, that of high lightness of green is described as a point GL_{High}, and so forth.

As described above, the hue and lightness values of the control points are determined. Furthermore, reduction ratios are set at the respective control points (S2). The reduction ratio indicates the percentages of the area of the colorimetrical matching region corresponding to each control point to that of the printer gamut. More specifically, the distance that connects the convergence point O (described later) of mapping and each grid point of the printer gamut is defined as 100%, and a reduction ratio with respect to this is set. For example, when the distance from the convergence point O of the colorimetrical matching region to the printer gamut is set to be 70% of the area of the printer gamut, a reduction ratio=70% is set at all the control points. When the high-lightness region of the green region (a region that Lab values are about (87, −86, 83)) is set to be broader, for example, a reduction ratio=90% is set at a control point GL_{High}, and a reduction ratio=70% is set at other control points. In this case, since the colorimetrical matching region is set inside the printer gamut, a reduction ratio which exceeds 100% must not be set.

A method of setting the colorimetrical matching region by applying the reduction ratios to all the grid points of the printer gamut (S3) will be described below. Assume that a reduction ratio=90% is set at a high-lightness control point GL_{High} at the hue value of green of the basic color, and a reduction ratio=70% is set at other control points.

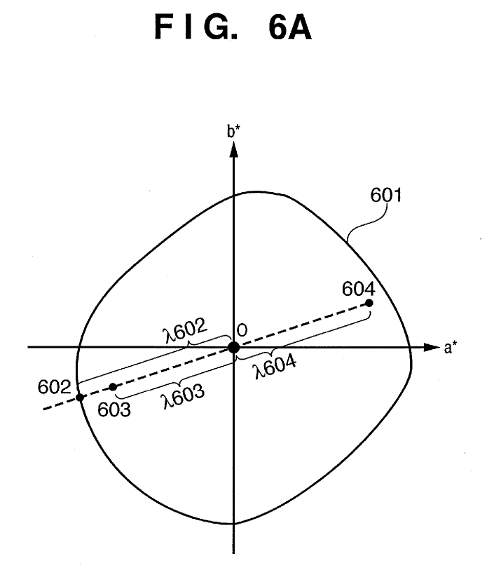

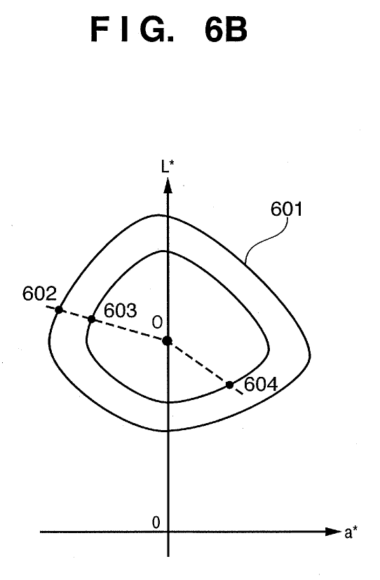

FIG. 6A shows an a*b* plane of a printer gamut 601, and FIG. 6B shows an L*a* plane of the printer gamut 601. In these figures, points 602, 603, and 604 are grid points of the printer gamut, and a point O is a convergence point. Also, let λ602 be the distance from the convergence point O to the grid point 602, λ603 be that to the grid point 603, and λ604 be that to the grid point 604.

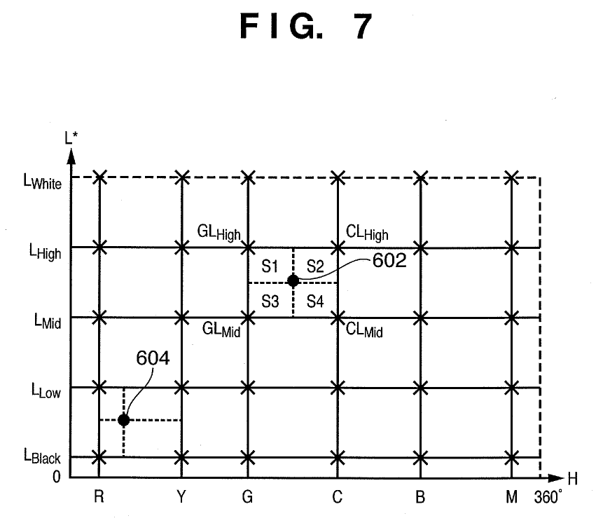

The following explanation will be given taking the grid point 602 as an example first. The hue value is calculated from the L*a*b* values of he grid point 602 using equation (1). Then, this grid point 602 is plotted on the view of the control points shown in FIG. 5. FIG. 7 shows a state wherein the grid point 602 is plotted on the view showing the control points.

Next, four control points which surround the grid point 602 and are closest to it are searched for. In the example shown in FIG. 7, control points GL_{Mid}, GL_{High}, CL_{Mid}, and CL_{High} are obtained. Furthermore, areas S1 to S4 of rectangles defined by the grid point 602 and the respective control points are calculated. Let S1 be the area of the rectangle formed by the grid point 602 and the point GL_{High}, S2 be that of the rectangle formed with the point CL_{High}, S3 be that of the rectangle formed with the point GL_{Mid}, and S4 be that of the rectangle formed with the point CL_{Mid}. Also, let S be the total of areas S1 to S4. Furthermore, a reduction ratio R at the grid point 602 is calculated based on the reduction ratios set for these control points using an area interpolation method given by:
R=(S1·R4+S2·R3+S3·R2+S4·R1)/S [%] (2)
where R1 is a reduction ratio=90% of the control point GL_{High},

R2 is a reduction ratio=70% of the control point CL_{High},

R3 is a reduction ratio=70% of the control point GL_{Mid}, and

R4 is a reduction ratio=70% of the control point CL_{Mid}.

Then, a distance λ′602 after reduction is calculated by multiplying the distance λ602 by the reduction ratio R, as indicated by:
λ′602=λ602×R/100 (3)

That is, a position of the distance λ′602 on a line which runs from the convergence point O to the grid point 602 is a grid point 602′ after reduction. The reduction ratio R of the grid point 603 is the same as that of the grid point 602. A grid point 603′ after reduction is determined by multiplying the distance λ603 from the convergence point O to the grid point 603 by the reduction ratio R.

On the other hand, the grid point 604 is surrounded by control points RL_{Black}, RL_{Low}, YL_{Black}, and YL_{Low}, as shown in FIG. 7. Since the reduction ratios set at these control points are 70%, the reduction ratio R of the grid point 604 is 70% without calculating equation (2). That is, a grid point 604′ after reduction is located at a distance of 70% of the distance λ604 from the convergence point O to the grid point 604.

By applying the aforementioned processing to all the grid points of the printer gamut, the region is obtained by reducing the printer gamut according to the colors of the control points. In this embodiment, the control points are the intersections between the hue values of the six basic colors and the specified lightness values. However, the present invention is not limited to such specific control points. For example, in order to broaden the region of hue of a memory color such as a flesh color (Lab values are about (80, 16 28)) or the like which is given an importance in reproduction of a photo, it is effective to define a control point by the central hue and lightness of a flesh color region, and to set a high reduction ratio at this control point. Also, in case of a printer which mounts spot color inks, it is effective to broaden the region of each spot color by defining a control point by the hue and lightness of that spot color ink. Note that the memory color such as a flesh color or the like, the colors of spot color inks, the six basic colors, user designated colors, and the like are important colors.

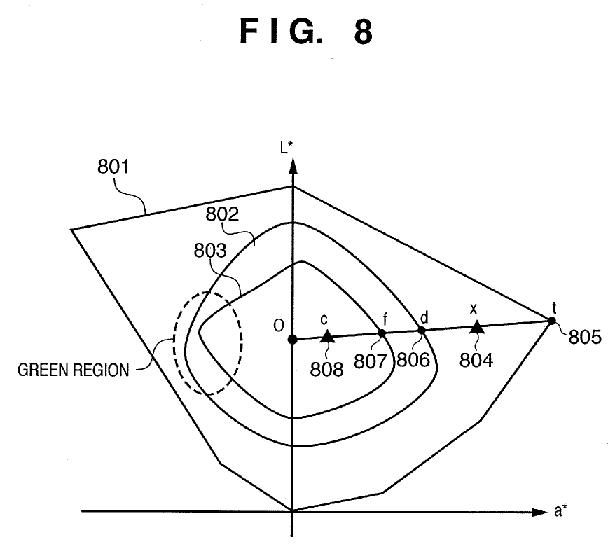

FIG. 8 is a view for explaining mapping when the colorimetrical matching region is set, and shows an L*a* plane of an sRGB color space 801, printer gamut 802, and colorimetrical matching region 803. In the colorimetrical matching region 803, a region which is colorimetrical matching to the green region indicated by the broken line is broadened in comparison with other hue regions, and the remaining colorimetrical matching region has an area about 70% of the printer gamut 802.

Furthermore, in FIG. 8, a point O represents a convergence point, and points 804 and 808 represent grid points on the sRGB color space 801. Since the grid point 808 is located within the colorimetrical matching region 803, its color is reproduced based on colorimetrical matching without being mapped. Whether a grid point on the sRGB color space 801 is located inside or outside the colorimetrical matching region 803, can be easily determined by executing, e.g., the following inside/outside determination processing (S4).

Initially, a vector which connects a point to be determined (arbitrary grid point) and the convergence point O inside the gamut (to be referred to as a “source vector” hereinafter) is calculated. Furthermore, a vector which extends from the convergence point O and intersects the boundary of the gamut via the point to be determined (to be referred to as a “gamut vector” hereinafter) is calculated. The length of the source vector is compared with that of the gamut vector. If the length of the source vector > that of the gamut vector, it is determined that the point to be determined falls inside the gamut. If the length of the source vector ≦ that of the gamut vector, it is determined that the point to be determined falls outside the gamut.

Next, a distance x between the convergence point O and the grid point 804 is calculated. Since the grid point 804 falls outside the colorimetrical matching region 803, it is mapped on the printer gamut 802 outside the colorimetrical matching region 803 (S5). A line which extends from the convergence point O and intersects the boundary of the sRGB color space 801 via the grid point 804 is drawn. A point where the line intersects with the boundary of the sRGB color space 801, a point 806 where it intersects with the boundary of the printer gamut 802, and a point 807 where it intersects with the boundary of the colorimetrical matching region 803 are searched for. Note that let t, d, and f be the distances from the convergence point O to the respective points 805, 806, and 807.

Based on the distances x, t, d, and f, the grid point 804 is mapped on the printer gamut 802. A grid point 804′ after mapping is located at a distance x′ which is located on the line that connects the convergence point O and grid point 804 and is calculated by a mapping function given by:
x=(d−f)(x−f)/(t−f)+f (4)
where x is the distance between the convergence point O and the grid point 804,

t is the distance between the convergence point O and the intersection 805 of the boundary of the sRGB color space 801,

d is the distance between the convergence point O and the intersection 806 of the boundary of the printer gamut 802, and

f is the distance between the convergence point O and the intersection 807 of the boundary of the colorimetrical matching region 803.

Note that the mapping function need not always be a linear function, and a multi-degree function that burns out tone as a grid point is located outside the gamut or a similar function may be used.

In this manner, steps S4 and S5 are repeated until it is determined in step S6 that all grid points on the sRGB color space 801 except for those inside the colorimetrical matching region 802 have been mapped. When the sRGB color space 801 is mapped on the printer gamut 802 to set a broader colorimetrical matching region 803 in correspondence with the green region, colors in the high-saturation region of green which have less chances to be input are mapped to be relatively burnt out. Since the colors of the low-saturation region of green which have many chances to be input readily enter the colorimetrical matching region 803, colorimetrically approximated color reproduction can be obtained.

In the description of the above example, the colorimetrical matching region of the low-saturation region of green is set to be broad. However, the present invention is not limited to this. For example, in photo reproduction, an importance is particularly attached to color reproduction of flesh color. When a lightness drop or saturation drop due to mapping stands out, the method of setting the colorimetrical matching region can be controlled so that this flesh color region falls inside the colorimetrical matching region.

Since yellow (a color that Lab values are about (97, −21, 94)) on the sRGB color space is a high-saturation color, its color burning-out relatively does not stand out, but its lightness drop readily stands out. Hence, it is effective to broaden a colorimetrical matching region of a high-lightness region where the yellow region of the sRGB color space is located. On the other hand, upon printing a photo taken underwater, it is desirable to hold the tone of the blue region (a region that Lab values are about (43, −2, −40)). In this case, by setting a narrow colorimetrical matching region of the blue region to broaden a region to be mapped, the tone balance improves. In this manner, since there are various features depending on colors and gamuts, it is effective to adaptively set the colorimetrical matching region to exploit such features.

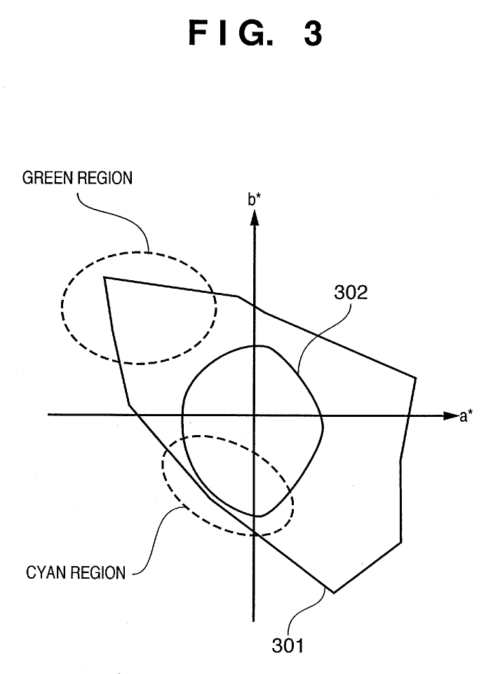

As shown in FIG. 3, the shape of the sRGB color space is different from that of the printer gamut. For example, the green region and the magenta region (a region that Lab values are about (60, 98, −60)) of the sRGB color space are considerably broader than those of the printer gamut. On the other hand, the cyan region (a region that Lab values are about (91, −48, −14)) of the sRGB color space is substantially the same as that of the printer gamut. For this reason, by comparing the green and magenta regions with the cyan region, tones in the green and magenta regions tend to burn out. Hence, the distances from the convergence point O to the boundaries of the sRGB color space and printer gamut are compared for each hue value, and when the distance of the sRGB color space is larger than that of the printer gamut to some extent (that is, the printer gamut is narrower than the sRGB color space), a narrow colorimetrical matching region is set. In this manner, tone burning-out can be reduced.

As described above, it is effective to set the colorimetrical matching region in consideration of the difference between the shapes of the input color space and the gamut of the output device, so as to attain satisfactory color reproduction.

Furthermore, if a copy is assumed, the colorimetrical matching region of a region where the printer gamut is narrower than the sRGB color space must be broadened. In this way, abrupt saturation and lightness drops due to mapping are avoided, and color reproduction approximate to original colors can be made. In this manner, it is also important to appropriately set (deform) the colorimetrical matching region in consideration of the use applications of the devices.

In the above description, the sRGB color space is used as the input color space. However, the input color space is not limited to the sRGB color space. For this reason, recent digital cameras for professional users can handle an AdobeRGB color space which is proposed by Adobe® Systems Incorporated and has a broader gamut than the sRGB color space. In this case, the input color space is the AdobeRGB color space. A profile which has prevailed as the industry consensus standard of the CMS and is proposed by the International Color Consortium (ICC) specifies the CIEXYZ color space and CIELab color space under the D50 light source. That is, when the CMS using the ICC profile is to be implemented, the CIELab color space or CIEXYZ color space can be the input color space. In this manner, since there are various input color spaces, the shape of the colorimetrical matching region can be set (deformed) to an optimal one in accordance with the input color space and the gamut of the output device.

### Second Embodiment

Color processing according to the second embodiment of the present invention will be described below. Note that the same reference numerals in the second embodiment denote the same parts as in the first embodiment, and a detailed description thereof will be omitted.

As the second embodiment, a user interface (UI) of an image processing apparatus (color processing apparatus) which performs the aforementioned color processing will be described below. As in the first embodiment, an example in which the reduction ratio=90% is set at the high-lightness control point GL_{High} in the green region as the basic color of the sRGB color space, and the reduction ratio=70% is set at other control points to set a broader colorimetrical matching region of the high-lightness green region will be explained.

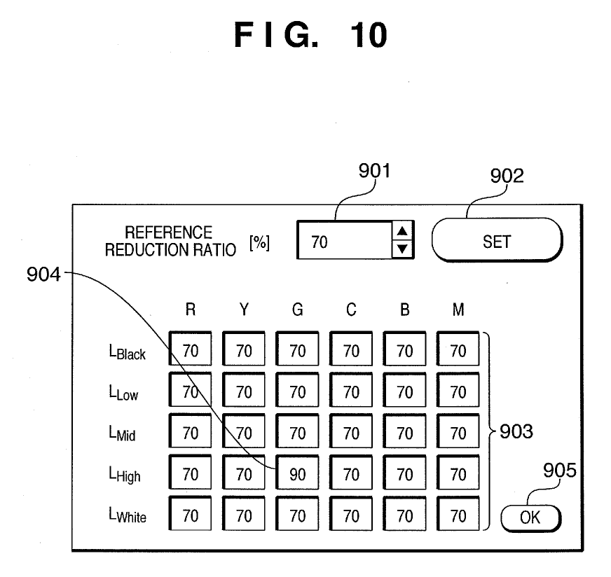

FIG. 10 shows an example of a UI used to set reduction ratios at all control points, i.e., a graphical user interface which is displayed on the image display device 203 by the image processor 208. Although not shown in FIG. 2, a keyboard and mouse are connected to the image processing apparatus 201, so that the user can operate the UI and can input numerical values and characters to the UI.

As in the first embodiment, assume that the control points are intersections between red R, yellow Y, green G, cyan C, blue B, and magenta M as the hue values of the basic color points on the sRGB color space, and lightness values which divide the range between the maximum value and minimum value of lightness L* into four.

The user sets the reduction ratios of the respective control points using edit boxes 903. Also, the user can set a uniform reduction ratio (reference reduction ratio) for all the control points using an edit control box 901. In the example shown in FIG. 10, 70% are set as the reference reduction ratio. When the user presses a “set” button 902, the reduction ratio=70% is set in all the edit boxes.

Next, when the user inputs “90” in an edit box 904 to increase the reduction ratio of the high-lightness point GL_{High} of green, and finally presses an “OK” button 905, the settings of the reduction ratios of the respective control points are validated. When the settings of the reduction ratios of the respective control points are validated, the image processor 208 sets a colorimetrical matching region by the sequence described in the first embodiment. Note that FIG. 10 exemplifies a case wherein a different reduction ratio is set for the high-lightness region of green. However, the present invention is not limited to this, and different reduction ratios can be set for all the control points.

When the reference reduction ratio has a large difference from the numerical value of a reduction ratio arbitrarily set by the user, the shape of the colorimetrical matching region may have a warp. Hence, when the reduction ratio of a given control point is compared to those of its surrounding control points, and their difference is larger than a predetermined value, a message “colorimetrical matching region will warp. Correct settings of reduction ratios” may be displayed, or processing for reverting a default reduction ratio or the like may be executed.

When the UI shown in FIG. 10 is used, the user can set arbitrary reduction ratios for all the control points in detail. Hence, the user can make fine adjustment as needed to implement mapping with higher precision.

On the other hand, some users want to set reduction ratios by a simpler method. In such case, a method to be described below is used. Note that the settings of the control points and reduction ratios are the same as those described above.

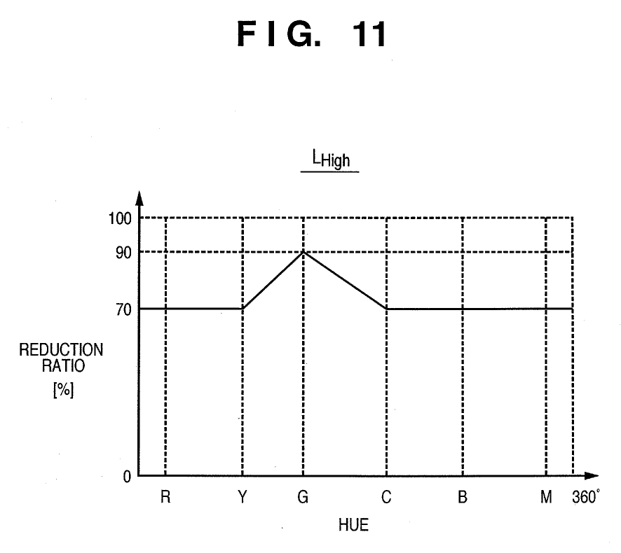

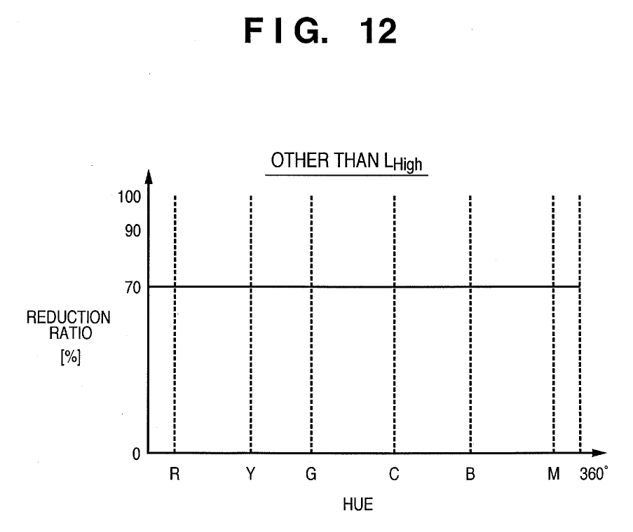

Upon setting the colorimetrical matching region, the control points and their reduction ratios can be set in accordance with the aforementioned characteristics of the color and gamut (like high-lightness green described above). For example, FIG. 11 is a graph which expresses, as a function, of the control points with lightness L_{High}. A reduction ratio=90% is set in correspondence with the hue value of green, and a reduction ratio=70% is set for other hue values. FIG. 12 shows reduction ratios of control points whose lightness is other than L_{High}. The reduction ratio of all the control points is set to be 70%. The functions which represent the relationship between the control points and reduction ratios shown in FIGS. 11 and 12 will be referred to as “control functions” hereinafter.

In this manner, when the image processor 208 holds control functions indicating the relationships between the control points and reduction ratios in advance, the user can easily execute mapping regardless of detailed settings of the colorimetrical matching region.

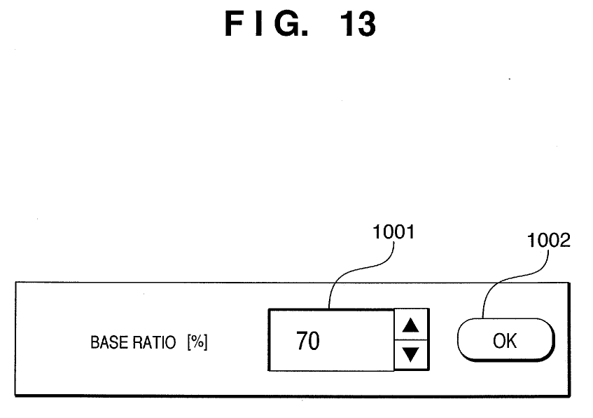

Furthermore, an example in which the area of the colorimetrical matching region based on the features of the color and gamut is changed while its shape remains the same will be described below. In this case, each control function remains the same, and the reduction ratio is uniformly increased or decreased. For example, the user displays a dialog shown in FIG. 13, and adjusts a base ratio corresponding to minimum reduction ratios of all the control points. The user increases the base ratio from 70% to 80% by operating an edit control box 1001, and then presses an “OK” button 1002. With this operation, the reduction ratio=90% of the control point GL_{High} is changed to 100%, and the reduction ratio=70% of other control points is changed to 80%. As a result, the colorimetrical matching region can be broadened while maintaining the relationship that assures a broader high-luminance green region.

In the above example, when a base ratio that exceeds 80% is set, the reduction ratio of the control point GL_{High} falls outside the printer gamut beyond 100%. In this case, the reduction ratio of a control point whose reduction ratio has reached 100% is fixed to 100%, and those of other control points are increased.

The method of simply increasing or decreasing the control function as a whole has been explained. Alternatively, a control function which inhibits the base ratio from being changed from 70%, and broadens, e.g., only the high-lightness green region while specializing it may be designated. In this case, the user sets the reduction ratio of the specialized region in place of the base ratio using the edit control box 1001 shown in FIG. 13.

### Third Embodiment

Color processing according to the third embodiment of the present invention will be described below. Note that the same reference numerals in the third embodiment denote the same parts as in the first and second embodiments, and a detailed description thereof will be omitted.

The user often wants to set the area of the colorimetrical matching region depending on the types and print qualities of print media and on the use applications of printed matters. As the third embodiment, the settings of the colorimetrical matching region when the types of print media are different will be described hereinafter.

An ink-jet printer can print on paper sheets such as plain paper, matt paper, exclusive photo paper, and the like. The gamuts of these print paper sheets become broader in the order of plain paper, matt patter, and exclusive photo paper. For this reason, color differences of high-lightness and high-saturation parts due to saturation and lightness drops as a result of mapping are small on exclusive photo paper, but they become large on plain paper.

Hence, the reduction ratios of a colorimetrical matching region which can be assumed in correspondence with respective print media are specified. A broad colorimetrical matching region is set in correspondence with the high-lightness region of green by assuming the features of the color and gamut in the same manner as described above.

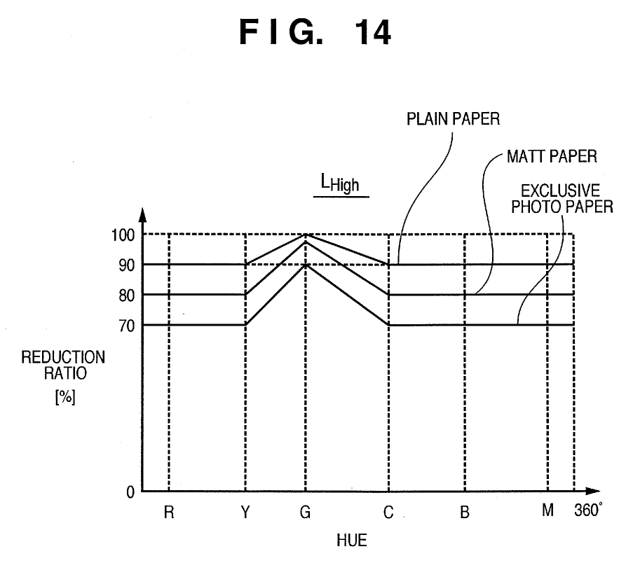

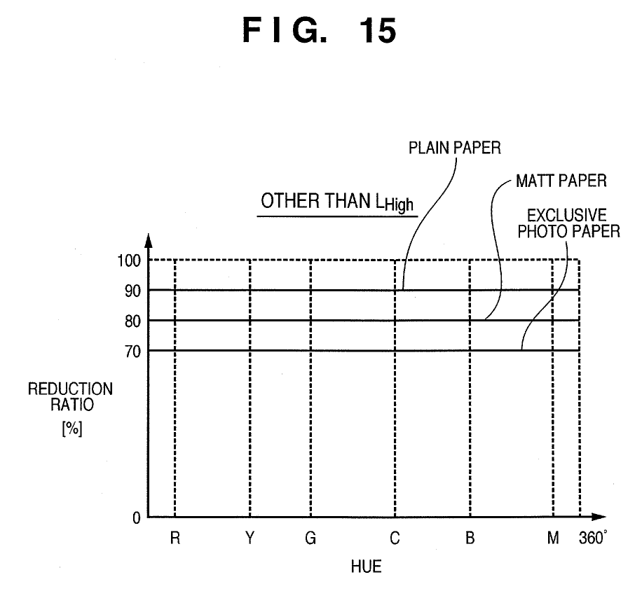

FIG. 14 shows an example of control functions of L_{High}, which are set in advance. FIG. 15 shows an example of control functions of control points other than L_{High}. For plain paper whose gamut is narrower than other print media, a high reduction ratio is set to increase the ratio of the colorimetrical matching region relative to the printer gamut. For matt paper and exclusive photo paper, a reduction ratio is set to be lower than that of plain paper. In this manner, negative effects such as a saturation drop resulting from mapping can be suppressed. Note that the control functions depending on the print media are not limited to those shown in FIGS. 14 and 15, and optimal control functions may be set as needed.

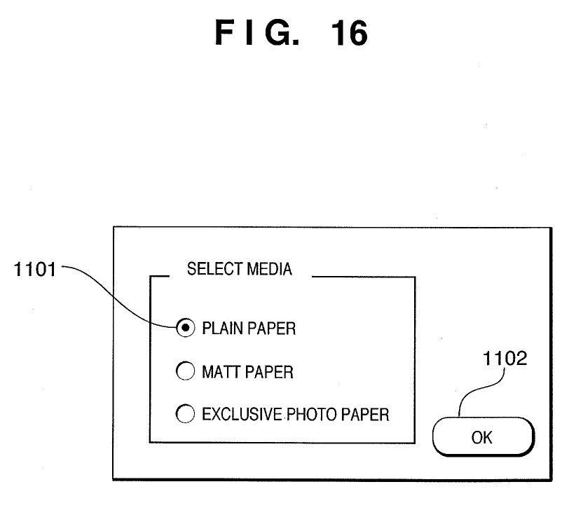

FIG. 16 shows a UI used to select the aforementioned control functions. The user selects a print medium used in printing by a radio button 1101, and then presses an “OK” button 1102. The image processor 208 sets a colorimetrical matching region using the control function corresponding to the selected print medium.

In this manner, by preparing for control functions according to the characteristics of different gamuts depending on print media (in other words, according to printer gamuts depending on print media or the types of printer gamuts), the user can easily set an optimal colorimetrical matching region. Furthermore, it is also effective to prepare for control functions according to required print qualities or the use applications of printed matters.

According to the above embodiments, a colorimetrical matching region can be adaptively set in accordance with the relationship between the input color space and the gamut of the output device, the use applications and features of the input and output devices, the features of colors, and the like. By perceptive mapping using the adaptively set colorimetrical matching region, satisfactory color reproduction that effectively uses the gamut of the output device can be realized without causing any tone burning-out in only a specific gamut.

### Other Embodiments

Note that the present invention can be applied to an apparatus comprising a single device or to system constituted by a plurality of devices.

Furthermore, the invention can be implemented by supplying a software program, which implements the functions of the foregoing embodiments, directly or indirectly to a system or apparatus, reading the supplied program code with a computer of the system or apparatus, and then executing the program code. In this case, so long as the system or apparatus has the functions of the program, the mode of implementation need not rely upon a program.

Accordingly, since the functions of the present invention are implemented by computer, the program code installed in the computer also implements the present invention. In other words, the claims of the present invention also cover a computer program for the purpose of implementing the functions of the present invention.

In this case, so long as the system or apparatus has the functions of the program, the program may be executed in any form, such as an object code, a program executed by an interpreter, or scrip data supplied to an operating system.

Example of storage media that can be used for supplying the program are a floppy disk, a hard disk, an optical disk, a magneto-optical disk, a CD-ROM, a CD-R, a CD-RW, a magnetic tape, a non-volatile type memory card, a ROM, and a DVD (DVD-ROM and a DVD-R).

As for the method of supplying the program, a client computer can be connected to a website on the Internet using a browser of the client computer, and the computer program of the present invention or an automatically-installable compressed file of the program can be downloaded to a recording medium such as a hard disk. Further, the program of the present invention can be supplied by dividing the program code constituting the program into a plurality of files and downloading the files from different websites. In other words, a WWW (World Wide Web) server that downloads, to multiple users, the program files that implement the functions of the present invention by computer is also covered by the claims of the present invention.

It is also possible to encrypt and store the program of the present invention on a storage medium such as a CD-ROM, distribute the storage medium to users, allow users who meet certain requirements to download decryption key information from a website via the Internet, and allow these users to decrypt the encrypted program by using the key information, whereby the program is installed in the user computer.

Besides the cases where the aforementioned functions according to the embodiments are implemented by executing the read program by computer, an operating system or the like running on the computer may perform all or a part of the actual processing so that the functions of the foregoing embodiments can be implemented by this processing.

Furthermore, after the program read from the storage medium is written to a function expansion board inserted into the computer or to a memory provided in a function expansion unit connected to the computer, a CPU or the like mounted on the function expansion board or function expansion unit performs all or a part of the actual processing so that the functions of the foregoing embodiments can be implemented by this processing.

As many apparently widely different embodiments of the present invention can be made without departing from the spirit and scope thereof, it is to be understood that the invention is not limited to the specific embodiments thereof except as defined in the appended claims.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2005-224594, filed Aug. 2, 2005, which is hereby incorporated by reference herein in its entirety.

What is claimed is:

1. A color processing method of converting a first gamut onto a second gamut, the method comprising the steps of:
setting a third gamut having a shape according to characteristics of a color or a gamut inside the second gamut;
mapping the first gamut included in the third gamut onto the second gamut which is colorimetrically matched or approximate to the first gamut; and
mapping the first gamut outside the third gamut onto the second gamut outside the third gamut.

2. The method according to claim 1, wherein the setting step includes a step of setting the third gamut in accordance with a type of the first gamut or the second gamut.

3. The method according to claim 1, wherein the setting step includes a step of setting the third gamut having a shape according to characteristics of an important color or an important gamut.

4. The method according to claim 3, wherein the important color includes at least one of a principal color, a memory color, and a spot color of the first gamut or the second gamut.

5. The method according to claim 4, wherein the principal color is at least one of six basic colors of the first gamut or the second gamut.

6. The method according to claim 4, wherein the spot color is a color of a spot color ink or a color designated by a user.

7. The method according to claim 1, wherein the setting step includes a step of setting the shape of the third gamut in accordance with a difference between a shape of the first gamut and a shape of the second gamut.

8. The method according to claim 1, wherein the setting step includes a step of setting the shape of the third gamut using a control function according to a difference between a shape of the first gamut and a shape of the second gamut.

9. The method according to claim 8, wherein the control function has characteristics that are set to broaden the third region for a region having a small shape difference, and to narrow down the third region for a region having a large shape difference.

10. The method according to claim 1, further comprising the step of displaying a user interface used to adjust the shape of the third gamut.

11. The method according to claim 1, wherein the setting step comprises the steps of:
setting a convergence point of the mapping in the second gamut;
setting a plurality of arbitrary control points in the first gamut on a hue-lightness plane of a uniform color system;
setting a first ratio which indicates a ratio to reduce the second gamut toward the convergence point at each of the plurality of control points;
setting, based on the first ratios set at the control points that surround a color value of a grid point on the second gamut, a second ratio corresponding to the grid point; and
setting a value obtained by multiplying a distance between the grid point on the second gamut and the convergence point by the second ratio as a distance between a grid point on the third gamut corresponding to the grid point, and the convergence point.

12. The method according to claim 1, wherein the second step includes a step of setting the third gamut in accordance with a use application or characteristics of an image processing apparatus.

13. A color processing apparatus for converting a first gamut onto a second gamut, the method comprising the steps of:
a setter, arranged to set a third gamut having a shape according to characteristics of a color or a gamut inside the second gamut; and
a mapper, arranged to map the first gamut included in the third gamut onto the second gamut which is colorimetrically matched or approximate to the first gamut, and to map the first gamut outside the third gamut onto the second gamut outside the third gamut.

14. A computer program for a color processing method of converting a first gamut onto a second gamut, the method comprising the steps of:
setting a third gamut having a shape according to characteristics of a color or a gamut inside the second gamut;
mapping the first gamut included in the third gamut onto the second gamut which is colorimetrically matched or approximate to the first gamut; and
mapping the first gamut outside the third gamut onto the second gamut outside the third gamut.

15. A computer program product stored on a computer readable medium comprising program code for a color processing method of converting a first gamut onto a second gamut, the method comprising the steps of:
setting a third gamut having a shape according to characteristics of a color or a gamut inside the second gamut;
mapping the first gamut included in the third gamut onto the second gamut which is colorimetrically matched or approximate to the first gamut; and
mapping the first gamut outside the third gamut onto the second gamut outside the third gamut.
